(19) United States
(12) Patent Application Publication
(10) Pub. No.: US 2020/0373490 A1
(43) Pub. Date: Nov. 26, 2020

(54) MASKS FOR VARIED PIXEL DENSITY AND METHOD OF MANUFACTURING DISPLAY PANEL USING THE SAME

(71) Applicant: Essential Products, Inc., Palo Alto, CA (US)

(72) Inventor: Jason Sean Gagne-Keats, Cupertino, CA (US)

(21) Appl. No.: 16/421,145

(22) Filed: May 23, 2019

(51) Int. Cl. H01L 51/00; H01L 51/56; C23C 14/04; C23C 14/12

(52) U.S. Cl. CPC H01L 51/0011; C23C 14/12; C23C 14/042; H01L 51/56

(57) ABSTRACT

Introduced here are technologies for positioning internal component(s) beneath pixelated display panels, as well as associated techniques for creating pixelated display panels. By lowering the pixel density in a segment of a display panel (also referred to as a “footprint”) that resides directly above an internal component, more light will be permitted to reach the internal component. Such technology may permit the internal component to be hidden when not performing a task. For example, if the internal component is an optical sensor, then sufficient light can be captured to form an image of good quality while also permitting the footprint to display digital content when the optical sensor is not in use.

### TECHNICAL FIELD

Various embodiments concern masks to be used in the fabrication of pixelated display panels, as well as associated techniques for making and using these masks.

### BACKGROUND

Many types of electronic devices exist today that utilize interfaces which are viewed on a display, such as a liquid crystal display, light-emitting diode display, etc. An individual typically interacts with these interfaces via an input device that is mechanically actuated (e.g., using buttons or keys) or electronically actuated (e.g., using a touch-sensitive display). The individual may view content on the display, and then interact with the interact with the content using the input device. For instance, an individual could choose to issue a command, make a selection, or move a cursor within the bounds of an interface. Touch-sensitive displays are becoming an increasingly popular option for many electronic devices due to the improved marketability and ease of use of such displays.

Most electronic devices include one or more cameras for capturing images of the surrounding environment, such as a front-facing camera that allows the individual to capture images or video while looking at the display. In combination with other components (e.g., microphones and speakers), front-facing cameras can also enable individuals to participate in two-way video calls facilitated by Google Hangouts™, Apple FaceTime®, or Skype™.

Front-facing cameras and these other components have conventionally been offset from the display. But this limits how much area on the front of the electronic device (also referred to as the “face” of the electronic device) can be devoted to the display. While some electronic devices have begun locating these objects within the bounds of the display (e.g., in a notch along the top of the display), such a design still limits the size of the display itself.

### SUMMARY

Introduced here are technologies for positioning internal components (e.g., optical sensors) beneath pixelated display panels, as well as associated techniques for creating pixelated display panels. More specifically, the pixel density can be lowered in a segment of a display panel (also referred to as a “footprint”) that resides directly above an internal component (e.g., an optical sensor). By lowering the pixel density in the footprint, more light will be permitted to reach the internal component positioned beneath the footprint.

Such technology enables internal components to be hidden when not performing a task. For example, if the internal component is an optical sensor, then sufficient light can be captured to form an image of good quality while also permitting the footprint to display digital content when the optical sensor is not in use. Although the digital content displayed within a footprint may be shown at a lower resolution than the remainder of the display panel, the technology eliminates the need for optical sensors to be placed within notches in the display panel or outside the bounds of the display panel entirely.

### BRIEF DESCRIPTION OF THE DRAWINGS

Various features and characteristics of the technology will become more apparent to those skilled in the art from a study of the Detailed Description in conjunction with the drawings. Embodiments of the technology are illustrated by way of example and not limitation in the drawings, in which like references may indicate similar elements.

FIG. 1 depicts an electronic device that includes a display and a front-facing camera disposed within a housing.

FIG. 2A is an exploded perspective view of a conventional display assembly for an electronic device.

FIG. 2B is a side view of an electronic device that illustrates how the camera is conventionally offset from the display assembly (also referred to as the “display stack”).

FIG. 3 illustrates several different views of electronic devices having a small form factor (also referred to as “small form factor devices” or “SFF devices”).

FIG. 4A depicts an electronic device that includes a display covering the entirety of its front face.

FIG. 4B illustrates how a front-facing camera (not shown) can be disposed within the housing beneath a segment (also referred to as a “footprint”) of the display having a lower pixel density than the reminder of the display.

FIG. 5 depicts a flow diagram of a process for selectively exposing a component housed within an electronic device beneath a pixelated segment of a display.

FIG. 6 includes two examples of pixel arrangements—a red-green-blue (RGB) stripe arrangement and a PenTile RGB arrangement.

FIG. 7 depicts a normal pixel layout and two modified pixel layouts having pixel densities of one-half and one-quarter of the normal pixel layout.

FIG. 8 depicts a process for creating a display that includes at least two segments having different pixel densities.

FIG. 9 depicts a flow diagram of another process for creating a display that includes at least two segments having different pixel densities.

FIG. 10 depicts a flow diagram of a process for manufacturing a mask to be used in the fabrication of displays for electronic devices.

FIG. 11 is a block diagram illustrating an example of a processing system in which at least some operations described herein can be implemented.

The drawings depict various embodiments for the purpose of illustration only. Those skilled in the art will recognize that alternative embodiments may be employed without departing from the principles of the technology. Accordingly, while specific embodiments are shown in the drawings, the technology is amenable to various modifications.

### DETAILED DESCRIPTION

Introduced here are technologies for positioning internal components (e.g., optical sensors) beneath pixelated display panels, as well as associated techniques for creating pixelated display panels. More specifically, the pixel density can be lowered in a segment of a display panel (also referred to as a “footprint”) that resides directly above an internal component (e.g., an optical sensor).

Some amount of light will be transmitted through a display panel regardless of its resolution. As the pixel density increases, transmittance will decrease. By lowering the pixel density in the footprint, more light will be permitted to reach the internal component positioned beneath the footprint. Thus, the footprint can be thought of as a light-transmissive hole in the display panel that is also capable of showing digital content.

Such technology enables internal components to be hidden when not performing a task. For example, if the internal component is an optical sensor, then sufficient light can be captured to form an image of good quality while also permitting the footprint to display digital content when the optical sensor is not in use. Other examples of internal components include fingerprint sensors, infrared sensors, ambient light sensors, etc. Nearly any component configured to reside within an electronic device and observe/monitor the ambient environment could be positioned beneath a footprint in a display panel. Although the digital content displayed within a footprint may be shown at a lower resolution than the remainder of the display panel, the technology eliminates the need for optical sensors to be placed within notches in the display panel or outside the bounds of the display panel entirely.

An electronic device (e.g., a mobile phone) can cause digital content to be shown within the footprint. Then, responsive to receiving input indicative of a request to use an internal component positioned beneath the footprint, the electronic device can expose the internal component. For example, the electronic device may simply stop showing digital content within the footprint when a user intends to capture an image using an optical sensor.

Other embodiments concern a display panel having a permanent hole (also referred to as an “aperture”) defined therethrough. In such embodiments, various components (e.g., a display layer and a touch circuitry layer) may extend around a periphery of the aperture. The aperture may reside entirely within the bounds of the display panel. Thus, light received by an internal component disposed within the bounds of the aperture may need to travel through the aperture before being received by the internal component.

The term “optical sensor” or “camera” may be used throughout the Detailed Description with respect to various embodiments. However, those skilled in the art will recognize that the technology is equally applicable to other components (e.g., sensors, such as proximity sensors and ambient light sensors, and light sources, such as light-emitting diodes) that could be housed within an electronic device. Any of these internal components could be hidden beneath a segment of the display panel while not in use.

The technology can be embodied using special-purpose hardware (e.g., circuitry), programmable circuitry appropriately programmed with software and/or firmware, or a combination of special-purpose hardware and programmable circuitry. Accordingly, embodiments may include a machine-readable medium having instructions that may be used to program an electronic device to facilitate the creation of a display panel having a pixel layout of varying density. The pixel layout may be defined by a custom mask that causes pixel density to be lower in the region of the optical sensor.

### Terminology

References in this description to “an embodiment” or “one embodiment” means that the particular feature, function, structure, or characteristic being described is included in at least one embodiment. Occurrences of such phrases do not necessarily refer to the same embodiment, nor are they necessarily referring to alternative embodiments that are mutually exclusive of one another.

Unless the context clearly requires otherwise, the words “comprise” and “comprising” are to be construed in an inclusive sense rather than an exclusive or exhaustive sense (i.e., in the sense of “including but not limited to”). The terms “connected,” “coupled,” or any variant thereof is intended to include any connection or coupling between two or more elements, either direct or indirect. The coupling/connection can be physical, logical, or a combination thereof. For example, devices may be electrically or communicatively coupled to one another despite not sharing a physical connection.

The term “based on” is also to be construed in an inclusive sense rather than an exclusive or exhaustive sense. Thus, unless otherwise noted, the term “based on” is intended to mean “based at least in part on.”

The term “module” refers broadly to software components, hardware components, and/or firmware components. Modules are typically functional components that can generate useful data or other output(s) based on specified input(s). A module may be self-contained. A computer program may include one or more modules. Accordingly, a computer program may include multiple modules responsible for completing different tasks or a single module responsible for completing all tasks.

When used in reference to a list of multiple items, the word “or” is intended to cover all of the following interpretations: any of the items in the list, all of the items in the list, and any combination of items in the list.

The sequences of steps performed in any of the processes described here are exemplary. However, unless contrary to physical possibility, the steps may be performed in various sequences and combinations. For example, steps could be added to, or removed from, the processes described here. Similarly, steps could be replaced or reordered. Therefore, descriptions of any processes are intended to be open-ended.

### Technology Overview

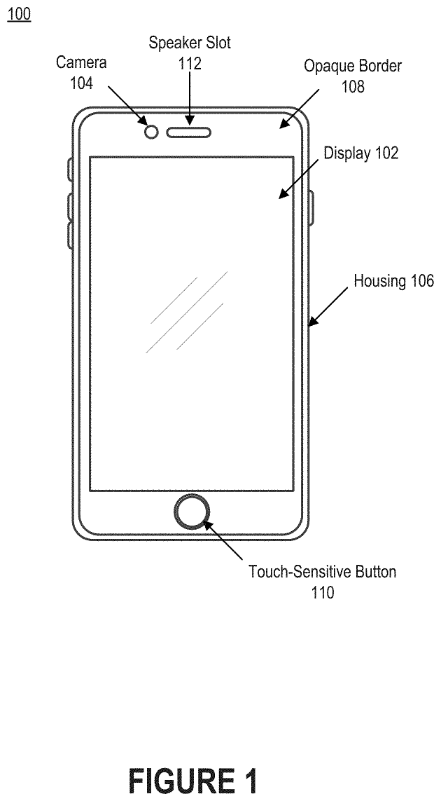

FIG. 1 depicts an electronic device 100 that includes a display 102 and a front-facing camera 104 disposed within a housing 106. Here, the electronic device 100 is a mobile phone. However, those skilled in the art will recognize that the technology introduced here could be readily adapted for other types of electronic devices.

The camera 104 on conventional electronic devices is usually set within a notch in the display 102 or offset from the display 102 entirely, which limits the size of the display 102. For example, the camera 104 may be located within an opaque border 108 surrounding the display 102 that is not responsive to user interactions (i.e., is not touch sensitive). The opaque border 108 is often used to hide components that reside within the electronic device 100, such as sensors, connectors, power supply, etc.

The camera 104 is typically one of multiple cameras included in the electronic device 100. For example, the electronic device 100 may include a rear-facing camera (not shown) that enables the user to capture images of objects residing behind the electronic device 100. The rear-facing and front-facing cameras can be, and often are, different types of cameras that are intended for different uses. For example, these cameras may be capable of capturing images having different resolutions. As another example, the cameras could be used with different lighting technologies (e.g., the rear-facing camera may have a stronger “flash” than the front-facing camera 104, the front-facing camera 104 may use the display 102 as a “flash,” etc.).

Other components may also limit the size of the display 102. For example, a touch-sensitive button 110 offset from the display 102 may enable the user to readily authorize use of the electronic device 100, interact with digital content shown on the display 102, etc. As another example, an ambient light sensor or a proximity sensor could be placed in/near a speaker slot 112 offset from the display 102. The speaker slot 112 is typically an opening in the protective substrate that enables audio to be projected by one or more speakers disposed within the housing 106 of the electronic device 100. Other speaker slots may be arranged along a side surface of the housing 106 proximate to the touch-sensitive button 110. A microphone (not shown) is also typically located proximate to the touch-sensitive button 110.

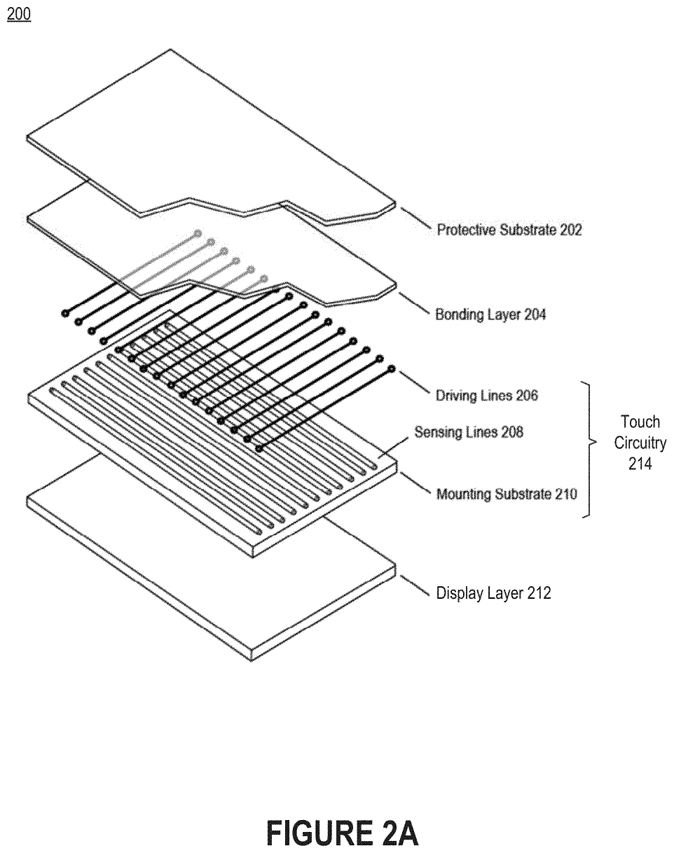

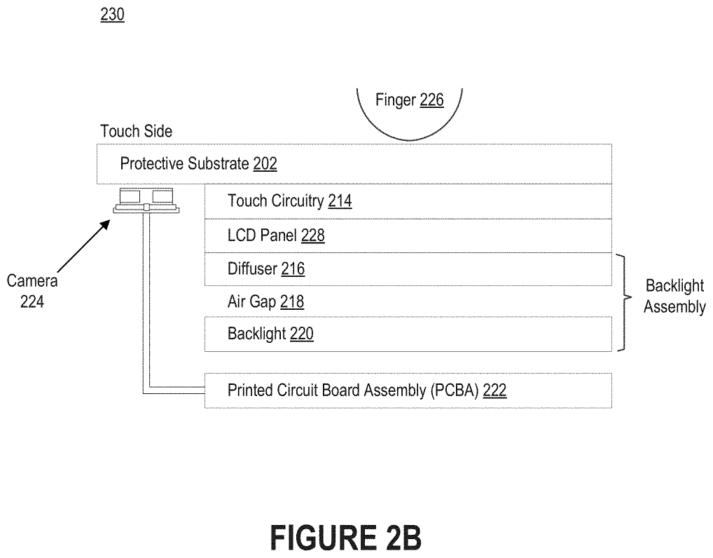

FIG. 2A is an exploded perspective view of a conventional display assembly 200 for an electronic device (e.g., electronic device 100 of FIG. 1). FIG. 2B, meanwhile, is a side view of an electronic device 230 that illustrates how the camera 224 is conventionally offset from the display assembly (also referred to as the “display stack”). The display assembly 200 can include a protective substrate 202, an optically-clear bonding layer 204, driving lines 206 and sensing lines 208 disposed on a mounting substrate 210, and a display layer 212. Various embodiments can include some or all of these layers, as well as other layers not shown here (e.g., optically-clear adhesive layers between the protective substrate 202 and the bonding layer 204, the mounting substrate 210 and the display layer 212, etc.).

The protective substrate 202 enables a user to interact with the display assembly 200. For example, the user may be able to contact an outer surface of the protective substrate 202 using a finger 226 without damaging the underlying layers. Generally, the protective substrate 202 is substantially or entirely transparent. The protective substrate 202 can be composed of glass, plastic, or any other suitable material (e.g., crystallized aluminum oxide).

Together, the driving lines 206 and sensing lines 208 include multiple electrodes (also referred to as “nodes”) that create a coordinate grid for the display assembly 200. The coordinate grid may be used by a processor on a printed circuit board assembly (PCBA) 222 to determine the intent of a user interaction with the protective substrate 202. The driving lines 206 and/or sensing lines 208 can be mounted to, or embedded within, a transparent mounting substrate 210. The mounting substrate 210 can be composed of glass, plastic, etc. The driving lines 206, sensing lines 208, and/or mounting substrate 210 are collectively referred to as “touch circuitry 214.”

An optically-clear bonding layer 204 may be used to bind the protective substrate 202 to the touch circuitry 214, which generates signals responsive to user interactions with the protective substrate 202. The bonding layer 204 can include an acrylic-based adhesive or a silicon-based adhesive, as well as one or more layers of indium-tin-oxide (ITO). The bonding layer 204 is preferably substantially or entirely transparent (e.g., greater than 99% light transmission). Moreover, the bonding layer 204 may display good adhesion to a variety of substrates, including glass, polyethylene (PET), polycarbonate (PC), polymethyl methacrylate (PMMA), etc.

A display layer 212 can be configured to display digital content with which the user can interact. The display layer 212 could include, for example, a liquid crystal display (LCD) panel 228 and a backlight assembly (e.g., a diffuser 216 and a backlight 220) that is able to illuminate the LCD panel 228. Other display technologies could also be used, such as light-emitting diodes (LEDs) organic light-emitting diodes (OLEDs), electrophoretic/electronic ink (e-ink), etc. Air gaps may be present between/within some of these layers. For example, an air gap 218 may be exist between the diffuser 216 and the backlight 220.

As shown in FIG. 2B, a camera 224 disposed within the electronic device 230 is typically coupled to a PCBA 222 that includes one or more components (e.g., processors) that facilitate the capturing of images using the camera 224. Although the camera 224 may be located below the protective substrate 202, the camera 224 is typically set within a notch in the display assembly 200 or outside of the bounds of the display assembly 200 entirely.

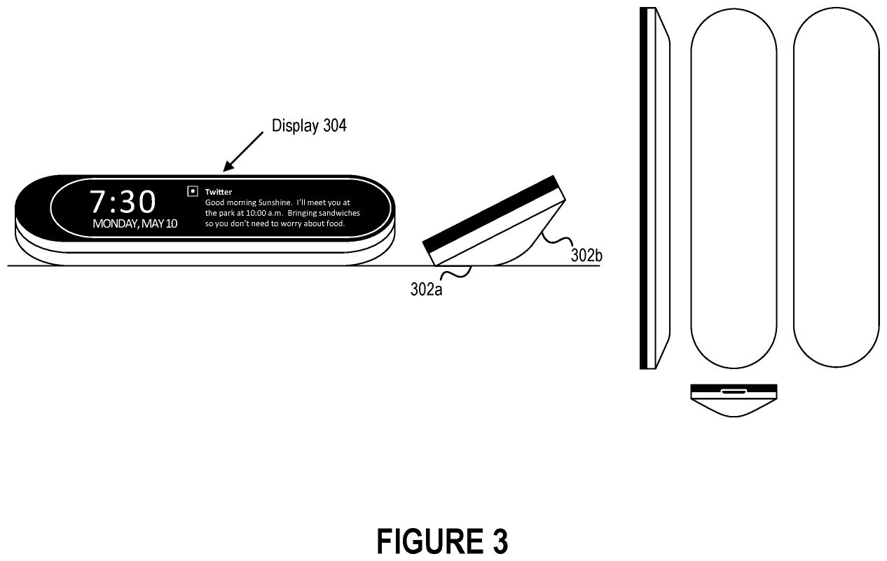

FIG. 3 illustrates several different views of electronic devices having a small form factor (also referred to as “small form factor devices” or “SFF devices”). SFF devices can have different form factors than conventional electronic devices.

One example of a SFF device is a small, pocket-sized mobile phone in the shape of a wedge-shaped prism that is approximately 1.5-3.5″ in width and 4-7″ in length. In such embodiments, the SFF device may be asymmetric such that multiple sides 302a-b may be used as built-in stands. Thus, the screen 304 of the SFF device may be positioned in different orientations based on which side is presently being used for support against a surface. For instance, one side may be better suited for reading text because it presents itself more vertically, while the other side may be better suited for displaying other information (e.g., time and notifications) with which the user is less likely to interact. Moreover, if laid on a surface in different orientations, the SFF device may have different screens, settings, features, etc., that it defaults to in terms of modalities.

SFF devices may also be configured to derive gestural input based on movement of the SFF devices themselves. For example, a SFF device may begin recording audio responsive to a determination that a user is holding the SFF device in a vertical orientation with the microphone near the mouth. As another example, a SFF device may begin playing audio responsive to a determination that a user has shaken the SSF device. Certain capabilities may be activated depending on the movement, orientation, and/or position of the SFF device at a given point in time. Thus, in some embodiments, the SFF device may automatically modify its own settings based on movement, orientation, and/or position. Consequently, the SFF device can automatically begin acting as a recording device based on these inputs rather than (or in addition to) speech commands that include “hot words” or “wake words” (e.g., “Okay, Google” or “Hello, Alexa”).

SFF devices can be configured to determine user intent without explicit verbal input (e.g., spoken commands) or tactile input (e.g., typed text or button interactions). Instead, a SFF device can readily understand user intent based on its natural movements, orientations, positions, or any combination thereof.

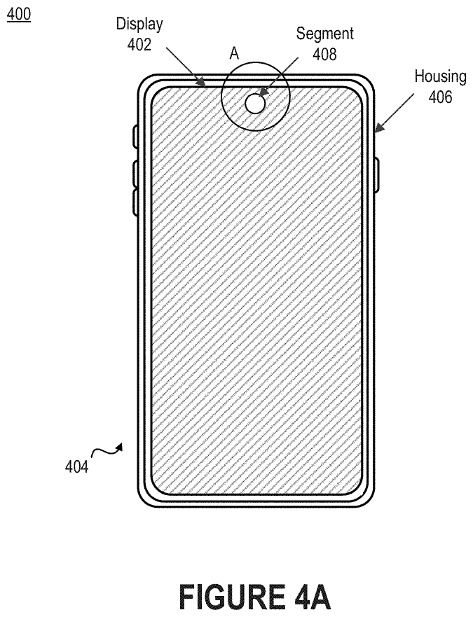

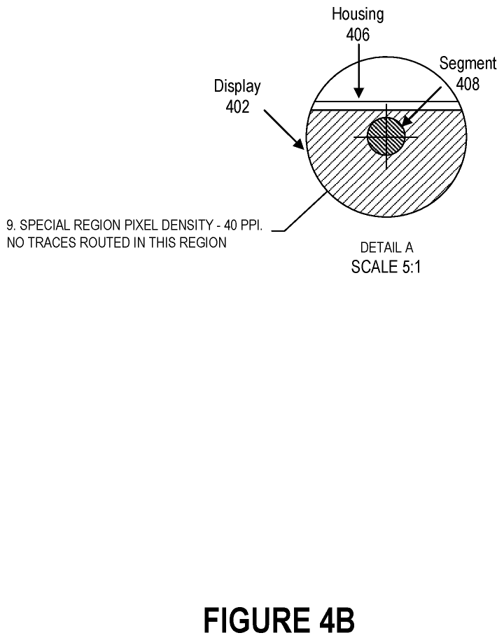

FIG. 4A depicts an electronic device 400 that includes a display 402 covering the entirety of its front face 404. FIG. 4B, meanwhile, illustrates how a front-facing camera (not shown) can be disposed within the housing 406 beneath a segment 408 (also referred to as a “footprint”) of the display 402 having a lower pixel density than the reminder of the display 402. While the electronic device 400 shown in FIGS. 4A-B is a mobile phone having a small form factor, those skilled in the art will recognize that the technology is similarly applicable to electronic devices having other form factors (e.g., conventional slate phones, tablet computers, laptop computers, and wearable devices such as watches and fitness trackers).

In some embodiments, the segment 408 resides entirely within the bounds of the display 402. Accordingly, as shown in FIG. 4B, the less-pixelated segment 408 may be completely surrounded by the reminder of the display 402. In such embodiments, the touch circuitry and display layer (e.g., LCD panel and backlight assembly) may entirely surround the segment 408, which could be arranged in a substantially co-planar relationship with the display layer. Alternatively, the display layer may entirely surround the segment 408, while the touch circuitry may at least partially overlay the segment 408. Thus, the segment 408 could still support some touch functionality, though the degree of touch functionality may be limited due to a lower density of touch elements.

In other embodiments, the segment 408 is bounded by the remainder of the display 402 on one or more sides. For example, the segment 408 may be arranged along a top side of the display 402 similar to a notch, though the user may not readily notice the display 402 includes a notch since the segment 408 is still capable of showing digital content.

As noted above, a camera (or some other optical sensor) can be disposed within the housing 406 beneath the segment 408. When the camera is not in use, digital content can be shown on the segment 408. Although the digital content displayed within the segment 408 will be shown at a lower resolution than the remainder of the display 402, the technology eliminates the need for optical sensors to be placed within notches that are readily noticeable or outside the bounds of the display 402 entirely. When the camera is in use, however, the segment 408 can become at least partially transparent. As further described below, transparency is achieved by refraining from showing digital content on the segment 408, which reduces the likelihood that light produced by the pixels in the segment 408 will mix with the light that penetrates the segment 408 and is detected by the camera. Such technology enables the camera to capture sufficient light to form an image of good quality.

While embodiments may be described in the context of less-pixelated segment beneath which are optical sensors, those skilled in the art will recognize that the features are similarly applicable to hiding/obscuring other components as well. For example, a less-pixelated segment could be positioned above a light source (e.g., a flash element such as a light-emitting diode), a fingerprint sensor, an infrared sensor, an ambient light sensor, etc. In some embodiments, an electronic device could include multiple less-pixelated segments corresponding to different internal components. For example, an electronic device could include a first less-pixelated segment positioned above a camera and a second less-pixelated segment positioned above a light source (e.g., a flash element for the camera) that operate independent of one another. In other embodiments, multiple internal components could be positioned beneath a single less-pixelate segment.

Different pixel densities may be used based on desired resolution, display size, etc. For example, the display 402 may naturally have a pixel density of 360 pixels per inch (PPI), while the segment 408 has a pixel density of 40 PPI or 80 PPI. To accomplish this, no traces may be routed in the region of the segment 408. If pixel density within the segment 408 is too high, then an optical sensor disposed beneath the segment 408 will not be able to receive enough light to generate images of good quality. Thus, there is a tradeoff between resolution of the segment 408 and the quality of images generated by the optical sensor.

Table I includes several different reference designs illustrating how decreasing the pixel density allows more light to reach the optical sensor. In some embodiments, the electronic device 400 is designed such that approximately 25 percent of available light is received by the optical sensor. Pixel densities of 40 and 80 PPI allow nearly 25 percent of available light to be transmitted through the segment 408, so a designer may choose either of these values. Here, for example, a manufacturer is likely to select 80 PPI since the resolution will double while only resulting in a decrease in light transmittance of only 0.59 percent. The reference designs provided in Table I have been included for the purpose of illustration. Embodiments of the pixel segment could have less than 40 PPI (e.g., 30 or 35 PPI), less than 80 PPI (e.g., 50, 60, or 70 PPI), more than 80 PPO (e.g., 85, 90, or 100 PPI), etc.

Table I: Measuring PPI versus transmittance for various designs.

TABLE I
Measuring PPI versus transmittance for various designs.

| | Design A | Design B | Design C | Design D | Design E |
|---|---|---|---|---|---|
| PPI | 267 | 134 | 80 | 40 | 0 |
| Transparent | 57.9% | 65.7% | 68.30% | 69.95% | 100% |
| Area | | | | | |
| Transmittance | 19.6% | 22.2% | 24.38% | 24.97% | 33.9% |
| (Without POL) | | | | | |
| Transmittance | 8.4% | 9.6% | 10.48% | 10.74% | 14.6% |
| (With POL) | | | | | |

Transmittance can be estimated as follows:

Transmittance=Transparent Area*POL Tr. (43%)*TFE Tr. (92%)*EL Tr. (50%)*PI Tr. (80%)*BF Tr. (97%)

As shown in Table I, there is a tradeoff between transmittance and display capabilities. Haze and sharpness of the transparent area can have a significant impact on performance of the optical sensor arranged beneath the segment 408. For instance, as the density of pixels increases, less light will be transmitted through the segment 408 toward the optical sensor. Accordingly, a manufacturer must choose a pixel density that is sufficient for display purposes and allows enough light through for high-quality images to be produced (e.g., following extensive processing operations to account for less light).

While the segment 408 is shown as a circular shape, those skilled in the art will recognize that segments may be other shapes as well. For example, the segment 408 may be in the form of a roughly rectangular notch along the top of the display 402. Moreover, as noted above, the display 402 may include multiple segments positioned within its bounds. These multiple segments may be different sizes, shapes, pixel resolutions, etc. For example, a first segment positioned above an optical sensor may have a first pixel density and a second segment positioned above a fingerprint sensor may have a second pixel density higher than the first pixel density. In some embodiments, the segment 408 has a gradient effect. Thus, pixel density near the epicenter of the segment 408 may be lower than pixel density around the periphery of the segment 408. Such a design may enable the segment 408 to more seamlessly camouflage into the display 402.

Generally, the segment 408 is not capable of receiving touch input because any underlying touch circuitry is routed around the corresponding internal component(s) (e.g., the optical sensor). That is, the segment 408 will typically not be touch sensitive. However, the segment 408 may retain some touch functionality in limited scenarios. For example, if the touch circuitry is partially or substantially transparent, the touch circuitry may be overlaid on at least a portion of the optical sensor. As another example, if density of the touch circuitry is lower in the segment 408, then the optical sensor may be arranged between adjacent driving lines and/or sensing lines (e.g., the optical sensor may be positioned between a series of nodes). As another example, touch circuitry capable of detecting off-axis touch input may be arranged proximate to the segment 408. In such embodiments, one or more sensors disposed adjacent the segment 408 may be able to detect touch events within the segment 408. For instance, ultrasonic sensor(s) may be arranged near the periphery of the segment 408 such that the ultrasonic sensor(s) can detect tough events occurring within the bounds of the segment 408.

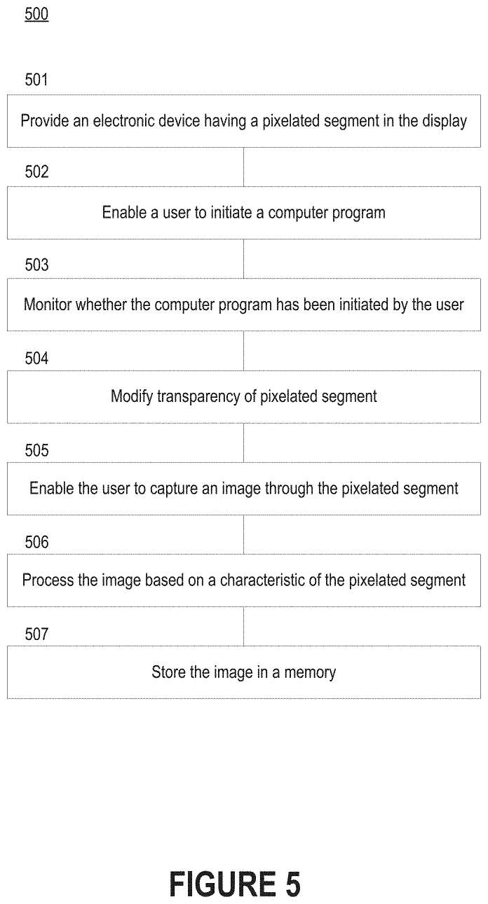

FIG. 5 depicts a flow diagram of a process 500 for selectively exposing a component housed within an electronic device beneath a pixelated segment of a display. While the process 500 of FIG. 5 is described in the context of a camera, the component could be another optical sensor, a light source, a fingerprint sensor, an infrared sensor, an ambient light sensor, etc. Moreover, the display may be included in a mobile phone, tablet computer, wearable device (e.g., a watch or fitness tracker), or any other electronic device having a feature/component that is desirable to hide when not in use.

Initially, an electronic device is provided that can include a protective substrate, a processor, a voltage source, and a display panel having a pixelated segment (step 501). The pixelated segment can be positioned entirely within the bounds of the display panel or along one edge of the display panel. Meanwhile, the protective substrate includes two sides—an outward-facing side with which a user is able to make contact and an inward-facing side that is directly adjacent to another layer of the display assembly (e.g., the touch circuitry).

In some embodiments, a user is able to initiate a computer program that is associated with the camera (step 502). For example, a user may initiate the computer program by performing a touch event (e.g., tapping the display) that involves a digital icon associated with the camera. Additionally or alternatively, the user may initiate the computer program by providing an audible command, performing a gesture, etc. Examples of computer programs include web browsers, desktop applications, mobile applications, and over-the-top (OTT) applications. The electronic device can continually monitor whether the computer program has been initiated by the user (step 503). Then, upon determining that the computer program has been initiated, the electronic device can modify the transparency of the pixelated segment (step 704). Although the term “transparency” is used herein, those skilled in the art will recognize that the transparency of individual pixels may not change. Instead, the electronic device may refrain from using the pixels within the pixelated segment for a specified duration. In some embodiments the duration is predetermined (e.g., 3, 5, or 7 seconds), while in other embodiments the duration extends indefinitely until the occurrence of a specified event (e.g., the user closes the computer program). Because the pixels in the pixelated segment are no longer producing light, the likelihood that light produced by these pixels will mix with the light that penetrates the pixelated segment is reduced. Thus, such action will effectively expose the camera through the display panel.

Thereafter, the electronic device can allow the user to capture an image (step 505). The electronic device may capture the image responsive to receiving input indicative of an interaction with the computer program (e.g., a tap of a digital icon) or the electronic device (e.g., a press of a mechanical button accessible through the housing of the electronic device). Moreover, the electronic device can process the image based on a characteristic of the pixelated segment and/or the camera (step 506). Generally, the electronic device processes the image by applying a series of processing operations. These processing operations may filter content, alter contrast/hue, etc. For example, the electronic device may apply a first set of processing operations in response to discovering that an image was captured through a pixelated segment having 22.2% transmittance. Meanwhile, the electronic device may apply a second set of processing operations in response to discovering that an image was captured through a pixelated segment having 24.38% transmittance. While the first and second sets of processing operations will generally be similar, they may differ in some respects. For instance, the first set of processing operations may include additional/different processing operations to “boost” the pixel data to account for the decreased transmittance. Thus, the image can be filtered based on the amount of light transmitted through the pixelated segment.

Images captured by the camera can be stored in a memory that is accessible to the electronic device (step 507). In some embodiments the memory is housed within the electronic device, while in other embodiments the memory is accessible to the electronic device across a network (e.g., as part of a cloud-based storage solution).

### Masks for Varied Pixel Density

In digital imaging, a pixel (also referred to as a “pel,” “dot,” or “picture element”) is the smallest addressable element in an all points addressable (APA) display. Said another way, a pixel is the smallest controllable element of a display. Because each pixel represents a sample of an original image, more pixels will result in a more accurate representation of the original image (also referred to as a “reproduction” or “image”). The number of pixels in a display is sometimes called the “resolution,” which can be expressed as a single number (e.g., 640 by 480).

For convenience, pixels are normally arranged in a regular two-dimensional grid. Such an arrangement allows many common operations to be implemented by uniformly applying the same operation to each pixel independently. Other arrangements of pixels are also possible, with some sampling patterns changing the shape/kernel of each pixel across a display. For example, some LCD panels use a staggered grid, where the red, green, and blue components of each pixel are sampled at slightly different locations. While features may be described in the context of certain pixel arrangements, those skilled in the art will recognize that the features are similarly applicable to other pixel arrangements.

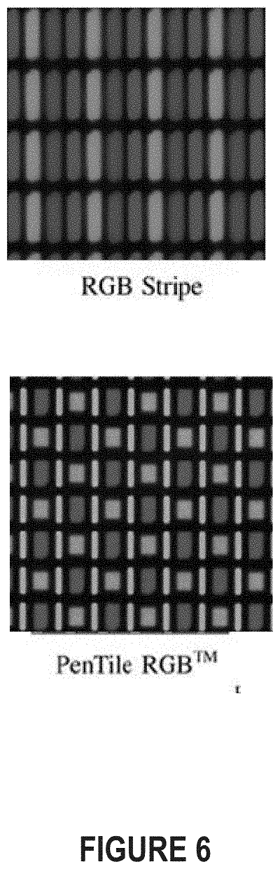

FIG. 6 includes two examples of pixel arrangements—a red-green-blue (RGB) stripe arrangement and a PenTile RGB arrangement. As noted above, the resolution of a display of an electronic device is measured in pixels. Generally, each pixel will include multiple sub-pixels corresponding to different colors (e.g., red, green, and blue). For example, a pixel may include three, five, or eight sub-pixels. In an RGB strip arrangement, these sub-pixels are the same size and have the same count. In comparison, the PenTile RGB arrangement employs a smaller green pixel, which results in a display that has fewer pixels than an RGB strip arrangement of the same resolution.

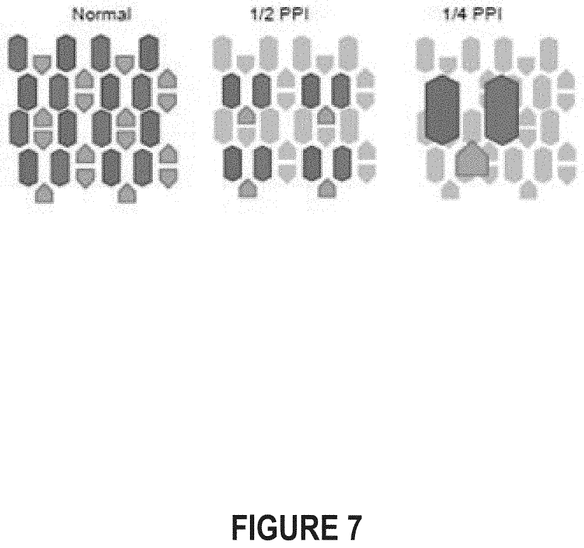

As noted above, by strategically varying the density of a pixel arrangement (also referred to as a “pixel layout”), a manufacturer can produce a display beneath which component(s) can be positioned. FIG. 7 depicts a normal pixel layout and two modified pixel layouts having pixel densities of one-half and one-quarter of the normal pixel layout. If the normal pixel layout has a pixel density of 360 PPI, for example, then the modified pixel layouts will have pixel densities of 180 PPI and 90 PP. As further described below, a manufacturer may produce a display having a modified pixel layout (e.g., having 80, 90, or 180 PPI) in at least one segment of the display and a normal pixel layout (e.g., having 360 PPI) in the remainder of the display.

For example, a manufacturer may employ a custom mask to produce displays having variable pixel densities. As shown in FIG. 7, the pixel layout can be modified in two different ways. In some embodiments, the custom mask causes some pixels within the segment to simply not be present. Said another way, the custom mask may cause some pixels (e.g., those that match a specified pattern) to be missing, as shown in the modified pixel layout having a pixel density of one-half of the normal pixel layout. In other embodiments, the custom mask causes pixels within the segment to be a different size, in a different pattern, etc. Here, for example, the modified pixel layout having a pixel density of one-quarter of the normal pixel layout has larger sub-pixels that are not offset from where the corresponding sub-pixels would be located.

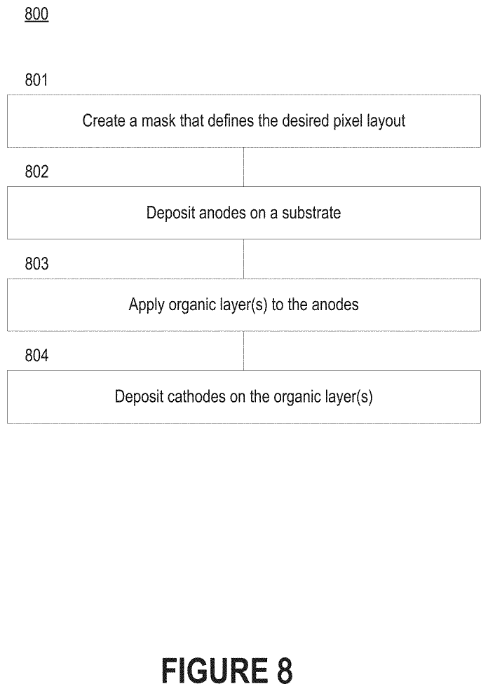

FIG. 8 depicts a flow diagram of a process 800 for creating a display that includes at least two segments having different pixel densities. Thus, the display can include a first pixelated segment having a first pixel density and a second pixelated segment having a second pixel density. These pixelated segments can be arranged in different positions with respect to one another. For example, the first pixelated segment may be positioned entirely within the second pixelated segment as shown in FIGS. 4A-B. Alternatively, the first pixelated segment may be arranged against at least one boundary of the second pixelated segment (e.g., the first pixelated segment may appear as a notch in the second pixelated segment). The design in which pixels are arranged in the first and second pixelated segments is often referred to as the “pixel layout” of the display.

OLED displays include multiple OLEDs configured to collectively display an image. Each OLED includes a substrate, an anode that removes electrons when a current is applied, a cathode that injects electrons when a current is applied, and a series of organic layers situated between the anode and cathode. The series of organic layers includes an emissive layer for transporting electrons from a cathode. The anode and cathode are configured to generate holes and electrons that recombine in the organic emission layer to form excitons, which drop at the bottom of a steady state to generate light of a predetermined wavelength. However, the color produced in response to an application of current is governed by the emissive layer, which is a film of organic compound(s).

In an OLED display, each pixel will normally include a red, green, and blue emissive layer to achieve full color display. Various techniques can be used to deposit these emissive layers, including vacuum deposition, jet printing, nozzle printing, laser ablation, laser-induced thermal imaging, and the like. Among these techniques, vacuum deposition is typically used to produce an OLED display having the best characteristics. However, vacuum deposition requires a fine metal mask (FMM) to generate the high-resolution pixel layout required by OLED displays. While the process 800 of FIG. 8 is described in the context of masks, those skilled in the art will recognize that the technology can be readily adapted for these other deposition techniques/mechanisms.

Accordingly, in order to create a display that includes at least two segments having different pixel densities, a mask must be created that defines the desired pixel layout (step 801). As noted above, the mask defines a first pixelated segment having a first pixel density and a second pixelated segment having a second pixel density. Said another way, the mask facilitates the creation of displays including at least two segments having different pixel densities—a footprint under which an optical sensor (or some other component) is positioned and the remainder of the display. The footprint has a lower pixel density than the remainder of the display. While the lower pixel density will cause the footprint to have a lower display resolution than the remainder of the display, it will also permit more light to permeate the display.

During the manufacturing process, anodes are initially deposited on a substrate (step 802). In some embodiments, the anodes are deposited on the substrate through the mask. Anodes are typically made of indium-tin-oxide (ITO), while the substrate is typically made of either glass, plastic, or foil.

Organic layer(s) are then applied to the anodes (step 803). These organic layer(s) can be made of either organic molecules or polymers. When organic molecules are used, there are two separate layers—the transport layer and the emissive layer. The transport layer serves to pass holes from the anodes, while the emissive layer passes electrons. When the holes and electrons interact, an excitation is emitted and light is created. Different colors are achieved with different organic layer materials. For example, if green is desired, then it is common to use the combination Mq³, where M is a Group III metal and q³ is 8-hydroxyquinolate. Blue can be achieved by using Alq₂OPh, while red can be achieved using perylene derivatives. When polymers are used, there is only a single layer.

Once a material has been chosen, a manufacturer can decide on an application technique. As noted above, organic layer(s) can be applied to the anodes in a variety of ways.

For example, polymers often use spin coating techniques. In spin coating, the organic material(s) are deposited in liquid form on the substrate in excess, and then the substrate is rotated at high speed to cause spreading of the organic material(s). Such action will cause the organic material(s) to form a thin layer that solidifies as it evaporates. However, spin coating is often undesirable for several reasons. For instance, the thin layer can have inconsistent thickness and smoothness. Accordingly, rather than (or in addition to) depositing the organic material(s) on the substrate in excess, the organic material(s) may be ejected onto the substrate through the mask much like inkjet printing.

As another example, small-molecule layers often use evaporative techniques. Thus, the organic layer(s) may be applied to the substrate through vacuum deposition that employs the mask to define the pixel layout.

Cathodes are then deposited onto the organic layer(s) (step 804). In some embodiments, the cathodes are deposited on the substrate through the mask. Cathodes are typically made of some sort of alloy. Examples of popular alloys include lithium/aluminum (Li:Al) and magnesium/silver (Mg:Ag). These alloys may be chosen because of their low work function, which enables electrons to be easily pumped into the organic layers. In some embodiments, the cathodes are made with a transparent material.

While the process 800 of FIG. 8 is described with respect to the manufacture of OLED displays, those skilled in the art will recognize that the process 800 is similarly applicable to other display technologies. For instance, if the manufacturer is interested in manufacturing a liquid crystal display (LCD) panel, the manufacturer can achieve a similar effect by varying the density of the thin-film transistors (TFTs), liquid crystals, and/or color filters. Thus, one region of an LCD panel may have a higher density of liquid crystals and color filters than another region of the LCD panel. Additional information on LCD and OLED displays is provided by Chen et al. in “Liquid crystal display and organic light-emitting diode display: present status and future perspectives,” Light: Science & Applications, 2018.

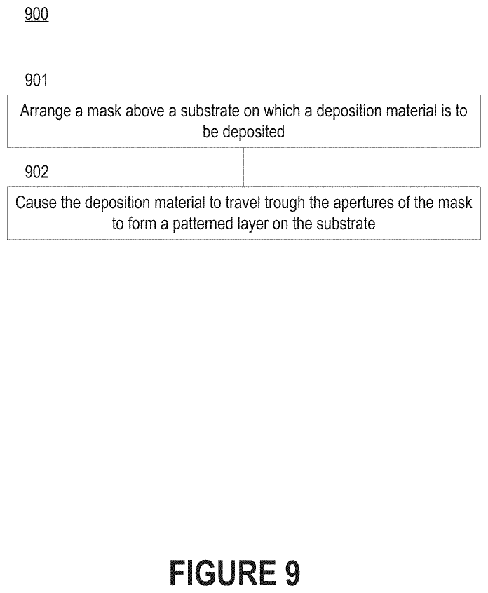

FIG. 9 depicts a flow diagram of another process 900 for creating a display that includes at least two segments having different pixel densities. Initially, a manufacturer can arrange a mask above a substrate on which a deposition material is to be deposited (step 901). The mask includes an arrangement of apertures through which the deposition material can travel, and, as noted above, the mask may include a first portion having a first density of apertures and a second portion having a second density of apertures. The apertures in the first and second portions may have different sizes, shapes, positions, or any combination thereof.

In some embodiments (e.g., when non-directional deposition is performed), the manufacturer may insert a spacing mechanism (also referred to as a “spacer”) between the mask and the substrate. The spacer may reduce direct contact between the mask and the substrate by maintaining a substantially consistent spacing of approximately 100 micrometers (μm), 200 μm, 300 μm, etc.

Thereafter, the manufacturer can cause the deposition material to travel through the apertures of the mask to form a patterned emissive layer (also referred to as a “patterned layer”) on the display assembly (step 902). As noted above, the manufacturer can cause the deposition material to be deposited on the display assembly in a variety of ways. In some embodiments, the manufacturer may place the display assembly in a vacuum chamber, heat the deposition material to a temperature sufficient to cause evaporation, and then allow the evaporated deposition material to condense on the surface of the display assembly in a thin film. In other embodiments, the manufacturer may place the display assembly in a low-pressure, hot-walled reactor chamber, heat the deposition material to a temperature sufficient to cause evaporation, and then transport the evaporated deposition material onto the surface of the display assembly using a carrier gas, such as argon or nitrogen. In other embodiments, the manufacturer may simply spray the deposition material onto the display assembly.

In some embodiments, the display assembly includes a substrate made of either glass or plastic, an anode layer configured to remove electrons when a current flows through the display assembly, and conducting layer(s) (also referred to as the “hole injection layer” and “hole transport layer”) configured to transport electronic holes from the anode layer to the patterned layer. In such embodiments, the patterned layer may be formed on the conducting layer(s) rather than the substrate. Moreover, the manufacturer may further place a cathode layer on top of the patterned layer formed by the deposition material. The cathode layer can be configured to inject electrons when the current flows through the display assembly. Note that the cathode layer may not necessary be directly adjacent to the patterned layer. Instead, an electron transport layer may be positioned between the patterned layer and the cathode layer.

The deposition material is one of multiple deposition materials that are deposited onto the display assembly through the apertures of the mask. Each deposition material of the multiple deposition materials may be a different organic material. In some embodiments, multiple deposition materials are deposited onto the display assembly in a series of stages using a single mask (e.g., by depositing the multiple deposition materials on top of one another). In other embodiments, multiple deposition materials are deposited onto the display assembly in a series of stages using separate masks. For example, a first organic material corresponding to a first color (e.g., red) may be deposited onto the display assembly through the apertures of a first mask, a second organic material corresponding to a second color (e.g., green) may be deposited onto the display assembly through the apertures of a second mask, etc. Together, the series of masks may enable the creation of a modified pixel layout as shown in FIG. 7.

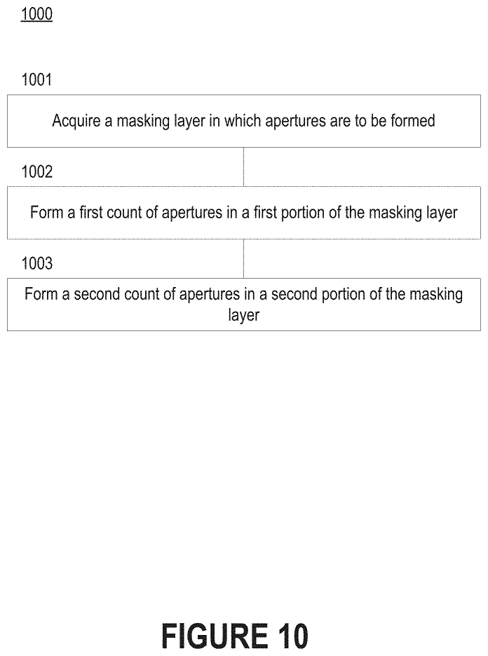

FIG. 10 depicts a flow diagram of a process 1000 for manufacturing a mask to be used in the fabrication of displays for electronic devices. Initially, a manufacturer can acquire a masking layer in which apertures are to be formed (step 1001). Generally, the masking layer is comprised of stainless steel, though the masking layer could be comprised of other non-reactive material(s). The masking layer is generally rectangular in shape (e.g., to confirm with the dimensions of the display assembly), and the thickness of the masking layer is normally 1.5-2.5 millimeters (mm) (and preferably 1.8-2.2 mm).

The manufacturer can then form a first count of apertures in a first portion of the masking layer (step 1002) and a second count of apertures in a second portion of the masking layer (step 1003). As noted above, the density of apertures in the first portion may be lower than the density of apertures in the second portion to allow more light to be transmitted through a segment of the display corresponding to the first portion. The manufacturer may form the apertures in the first and second portions of the masking layer with a stamping tool.

In some embodiments, the apertures in the first portion of the masking layer have different shapes, sizes, and/or positions than the apertures in the second portion of the masking layer. For example, there may be fewer apertures in the first portion of the masking layer, though these apertures may be larger in size (thereby resulting in larger sub-pixels, as shown in FIG. 7). As another example, the apertures in the masking layer may come in at least two designs having different shapes and/or sizes. For instance, the apertures corresponding to sub-pixels of a first color (e.g., red) may be a first design, while the apertures corresponding to sub-pixels of a second color (e.g., green) may be a second design. To produce the modified pixel layouts of FIG. 7, for example, the mask would have irregular pentagons for green sub-pixels and elongated hexagons for red and blue sub-pixels.

As further described above, the first portion may be positioned in several different locations. In some embodiments the first portion is entirely surrounded by the second portion, while in other embodiments the first portion is only partially surrounded by the second portion. If the masking layer includes a single lower-resolution portion, that portion will normally be centrally located along the width of the masking layer. However, if the masking layer includes multiple lower-resolution portions, these portions may be arranged symmetrically with respect to a widthwise midpoint of the masking layer. Alternatively, these portions may be arranged elsewhere (e.g., corresponding to the upper left portion of the display).

Generally, the distance between adjacent apertures is at least 90 μm but no more than 170 μm. The distance between adjacent apertures need not necessarily be consistent though. For example, in the case of the modified pixel layouts of FIG. 7, the apertures may be arranged such that the distance between the larger red and blue sub-pixels is greater than the distance between the larger red sub-pixel and the smaller green sub-pixel or the distance between the larger blue sub-pixel and the smaller green sub-pixel.

By depositing a deposition material on a display assembly through the apertures of the mask, the manufacturer (or some other manufacturer) can ensure the deposition material forms a patterned layer. While the process 1000 of FIG. 10 is described in the context of apertures for producing sub-pixels, those skilled in the art will recognize that an aperture could correspond to a sub-pixel, pixel, or pixel region such as a row or column (in which case another mask may define the pixel layout within the pixel region).

Unless contrary to physical possibility, it is envisioned that the steps described above may be performed in various sequences and combinations. For example, one manufacturer may be responsible for creating the mask (e.g., performing the process 1000 of FIG. 10), while another manufacturer may be responsible for creating the display (e.g., performing the process 900 of FIG. 9). As another example, a single manufacturer may be responsible for creating the mask (e.g., performing the process 1000 of FIG. 10) and creating the display (e.g., performing the process 900 of FIG. 9).

Other steps may also be included in some embodiments. For example, after depositing the organic material(s) on a substrate needed to reproduce a given color (e.g., red), the manufacturer may cure the organic material(s) by exposing substrate to a dryer, a light source (e.g., configured to emit ultraviolet radiation), etc. Then, the manufacturer may deposit the organic material(s) on the substrate needed to reproduce another color (e.g., green or blue).

### Processing System

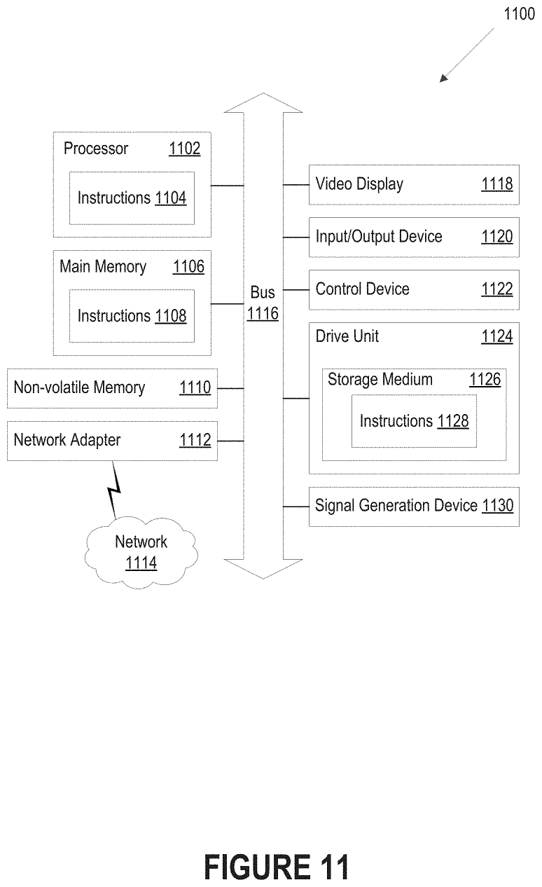

FIG. 11 is a block diagram illustrating an example of a processing system 1100 in which at least some operations described herein can be implemented. For example, some components of the processing system 1100 may be hosted on an electronic device with a display having variable pixel density. As another example, some components of the processing system 1100 may be hosted on an electronic device responsible for facilitating the manufacture of a display having variable pixel density.

The processing system 1100 may include one or more central processing units (“processors”) 1102, main memory 1106, non-volatile memory 1110, network adapter 1112 (e.g., network interface), video display 1118, input/output devices 1120, control device 1122 (e.g., keyboard and pointing devices), drive unit 1124 including a storage medium 1126, and signal generation device 1130 that are communicatively connected to a bus 1116. The bus 1116 is illustrated as an abstraction that represents one or more physical buses and/or point-to-point connections that are connected by appropriate bridges, adapters, or controllers. The bus 1116, therefore, can include a system bus, a Peripheral Component Interconnect (PCI) bus or PCI-Express bus, a HyperTransport or industry standard architecture (ISA) bus, a small computer system interface (SCSI) bus, a universal serial bus (USB), IIC (I2C) bus, or an Institute of Electrical and Electronics Engineers (IEEE) standard 1394 bus (also referred to as “Firewire”).

The processing system 1100 may share a similar computer processor architecture as that of a desktop computer, tablet computer, personal digital assistant (PDA), mobile phone, game console, music player, wearable electronic device (e.g., a watch or fitness tracker), network-connected (“smart”) device (e.g., a television or home assistant device), virtual/augmented reality systems (e.g., a head-mounted display), or another electronic device capable of executing a set of instructions (sequential or otherwise) that specify action(s) to be taken by the processing system 1100.

While the main memory 1106, non-volatile memory 1110, and storage medium 1126 (also called a “machine-readable medium”) are shown to be a single medium, the term “machine-readable medium” and “storage medium” should be taken to include a single medium or multiple media (e.g., a centralized/distributed database and/or associated caches and servers) that store one or more sets of instructions 1128. The term “machine-readable medium” and “storage medium” shall also be taken to include any medium that is capable of storing, encoding, or carrying a set of instructions for execution by the processing system 1100.

In general, the routines executed to implement the embodiments of the disclosure may be implemented as part of an operating system or a specific application, component, program, object, module, or sequence of instructions (collectively referred to as “computer programs”). The computer programs typically comprise one or more instructions (e.g., instructions 1104, 1108, 1128) set at various times in various memory and storage devices in a computing device. When read and executed by the one or more processors 1102, the instruction(s) cause the processing system 1100 to perform operations to execute elements involving the various aspects of the disclosure.

Moreover, while embodiments have been described in the context of fully functioning computing devices, those skilled in the art will appreciate that the various embodiments are capable of being distributed as a program product in a variety of forms. The disclosure applies regardless of the particular type of machine or computer-readable media used to actually effect the distribution.

Further examples of machine-readable storage media, machine-readable media, or computer-readable media include recordable-type media such as volatile and non-volatile memory devices 1110, floppy and other removable disks, hard disk drives, optical disks (e.g., Compact Disk Read-Only Memory (CD-ROMS), Digital Versatile Disks (DVDs)), and transmission-type media such as digital and analog communication links.

The network adapter 1112 enables the processing system 1100 to mediate data in a network 1114 with an entity that is external to the processing system 1100 through any communication protocol supported by the processing system 1100 and the external entity. The network adapter 1112 can include a network adaptor card, a wireless network interface card, a router, an access point, a wireless router, a switch, a multilayer switch, a protocol converter, a gateway, a bridge, bridge router, a hub, a digital media receiver, and/or a repeater.

The network adapter 1112 may include a firewall that governs and/or manages permission to access/proxy data in a computer network and tracks varying levels of trust between different machines and/or applications. The firewall can be any number of modules having any combination of hardware and/or software components able to enforce a predetermined set of access rights between a particular set of machines and applications, machines and machines, and/or applications and applications (e.g., to regulate the flow of traffic and resource sharing between these entities). The firewall may additionally manage and/or have access to an access control list that details permissions including the access and operation rights of an object by an individual, a machine, and/or an application, and the circumstances under which the permission rights stand.

The techniques introduced here can be implemented by programmable circuitry (e.g., one or more microprocessors), software and/or firmware, special-purpose hardwired (i.e., non-programmable) circuitry, or a combination of such forms. Special-purpose circuitry can be in the form of one or more application-specific integrated circuits (ASICs), programmable logic devices (PLDs), field-programmable gate arrays (FPGAs), etc.

### Remarks

The foregoing description of various embodiments of the claimed subject matter has been provided for the purposes of illustration and description. It is not intended to be exhaustive or to limit the claimed subject matter to the precise forms disclosed. Many modifications and variations will be apparent to one skilled in the art. Embodiments were chosen and described in order to best describe the principles of the invention and its practical applications, thereby enabling those skilled in the relevant art to understand the claimed subject matter, the various embodiments, and the various modifications that are suited to the particular uses contemplated.

Although the Detailed Description describes certain embodiments and the best mode contemplated, the technology can be practiced in many ways no matter how detailed the Detailed Description appears. Embodiments may vary considerably in their implementation details, while still being encompassed by the specification. Particular terminology used when describing certain features or aspects of various embodiments should not be taken to imply that the terminology is being redefined herein to be restricted to any specific characteristics, features, or aspects of the technology with which that terminology is associated. In general, the terms used in the following claims should not be construed to limit the technology to the specific embodiments disclosed in the specification, unless those terms are explicitly defined herein. Accordingly, the actual scope of the technology encompasses not only the disclosed embodiments, but also all equivalent ways of practicing or implementing the embodiments.

The language used in the specification has been principally selected for readability and instructional purposes. It may not have been selected to delineate or circumscribe the subject matter. It is therefore intended that the scope of the technology be limited not by this Detailed Description, but rather by any claims that issue on an application based hereon. Accordingly, the disclosure of various embodiments is intended to be illustrative, but not limiting, of the scope of the technology as set forth in the following claims.

What is claimed is:

1. A method for fabricating a display panel for an electronic device, the method comprising:
arranging a mask above a substrate on which a deposition material is to be deposited,
wherein the mask includes apertures formed therein, and
wherein the mask includes a first portion having a first density of apertures and a second portion having a second density of apertures; and
causing the deposition material to travel through the apertures of the mask to form a patterned layer on the substrate.

2. The method of claim 1, wherein the deposition material is one of multiple deposition materials deposited onto the display assembly through the apertures of the mask.

3. The method of claim 2, wherein each deposition material of the multiple deposition materials is an organic material.

4. The method of claim 1, further comprising:
placing the substrate in a vacuum chamber.

5. The method of claim 4, wherein said causing comprises:
heating the deposition material to a temperature sufficient to cause evaporation; and
allowing evaporated deposition material to condense on the substrate in a thin film.

6. The method of claim 1, further comprising:
placing the substrate in a low-pressure, hot-walled reactor chamber.

7. The method of claim 6, wherein said causing comprises:
heating the deposition material to a temperature sufficient to cause evaporation; and
transporting evaporated deposition material onto the substrate using a carrier gas.

8. The method of claim 1, wherein said causing comprises:
spraying the deposition material onto the substrate.

9. The method of claim 1, further comprising:
placing an anode layer on an upper surface of the substrate,
wherein the anode layer is configured to remove electrons when a current flows through the display panel; and
placing a conducting layer on an upper surface of the anode layer,
wherein the conducting layer is configured to transport electron holes from the anode layer.

10. The method of claim 9, wherein said causing causes the patterned layer to be formed on an upper surface of the conducting layer, and wherein the method further comprises:
placing a cathode layer on an upper surface of the patterned layer,
wherein the cathode layer is configured to inject electrons when the current flows through the display panel.

11. A mask used to fabricate an organic light-emitting diode (OLED) display panel having a varied pixel density, the mask comprising:
a masking layer having formed therein apertures through which at least one deposition material travels to form a patterned layer during fabrication of the OLED display panel,
wherein the masking layer includes a first region having a first density of apertures and a second region having a second density of apertures, and
wherein the first density is lower than the second density.

12. The mask of claim 11, wherein apertures in the first region have different shapes, different sizes, or any combination thereof than apertures in the second region.

13. The mask of claim 11, wherein each aperture in the masking layer is the same shape and the same size.

14. The mask of claim 11, wherein the apertures come in at least two designs of different shapes, different sizes, or any combination thereof.

15. The mask of claim 14, wherein a first design of the at least two designs corresponds to a first color of sub-pixels, and wherein a second design of the at least two designs corresponds to a second color of sub-pixels.

16. The mask of claim 11, wherein the first region is entirely surrounded by the second region.

17. The mask of claim 11, wherein the first region causes the OLED display panel to have a pixel density of no more than 100 pixels per inch (PPI) in a first segment, and wherein the second region causes the OLED display panel to have a pixel density of at least 300 PPI in a second segment.

18. The mask of claim 11, wherein the first region of the mask is circular in shape.

19. The mask of claim 11, wherein the first density of apertures allows at least 24 percent of available light to be transmitted through a corresponding first segment of the OLED display panel.

20. A method for manufacturing a mask to be used in the fabrication of a display panel for an electronic device, the method comprising:
receiving a masking layer in which apertures are to be formed,
wherein the apertures facilitate the formation of a patterned layer of deposition material during fabrication of a display panel; and
forming a first count of apertures in a first region of the masking layer; and
forming a second count of apertures in a second region of the masking layer,
wherein a first density of apertures in the first region is lower than a second density of apertures in the second region.

21. The method of claim 20, wherein apertures in the first region have different shapes, different sizes, or any combination thereof than apertures in the second region.

22. The method of claim 20, wherein the masking layer includes apertures of at least two designs of different shapes or different sizes.

23. The method of claim 22, wherein a first design of the at least two designs corresponds to a first color of sub-pixels, and wherein a second design of the at least two designs corresponds to a second color of sub-pixels.

24. The method of claim 20, wherein the masking layer is rectangular in shape, and wherein the first region is centrally located along a width of the masking layer.

25. The method of claim 24, wherein the first region is circular in shape, and wherein the first region is entirely surrounded by the second region.

26. The method of claim 24, wherein the first region is a notch in the second region.

27. The method of claim 20, wherein a distance between adjacent apertures is at least 90 micrometers (μm) and no more than 170 μm.

28. The method of claim 20, wherein the apertures of the masking layer include:
a first plurality of apertures corresponding to red sub-pixels;
a second plurality of apertures corresponding to green sub-pixels; and
a third plurality of apertures corresponding to blue sub-pixels.
